(19) United States
(12) Patent Application Publication
(10) Pub. No.: US 2025/0107369 A1
(43) Pub. Date: Mar. 27, 2025

(54) DISPLAY DEVICE AND MANUFACTURING METHOD THEREOF

(71) Applicant: Samsung Display Co., LTD., Yongin-si (KR)

(72) Inventors: SEUNGJAE KANG, Yongin-si (KR); HEEJU WOO, Yongin-si (KR); CHOLONG WON, Yongin-si (KR); DAEHWAN JANG, Yongin-si (KR)

(21) Appl. No.: 18/887,865

(22) Filed: Sep. 17, 2024

(30) Foreign Application Priority Data
Sep. 25, 2023 (KR) 10-2023-0128057

(51) Int. Cl. H10K 59/131; H10K 59/12

(52) U.S. Cl. CPC H10K 59/131; H10K 59/1201

(57) ABSTRACT

A display device includes: a display panel having a display region in which a pixel is disposed and a non-display region in which a pad electrode is disposed; a driving part disposed on the display panel and having a bump electrode disposed to correspond to the pad electrode; and an adhesive layer in contact with the pad electrode and the bump electrode. The pad electrode includes: a first connection pattern containing a conductive material; an auxiliary pattern disposed on the first connection pattern, protruding toward the bump electrode, and containing an insulating material; and a second connection pattern, which contains a conductive material, of which a portion is disposed on the auxiliary pattern, and in which an opening that exposes a portion of the auxiliary pattern is defined, and the auxiliary pattern includes a tip portion more protruding toward the opening than the first connection pattern.

This application claims priority to Korean Patent Application No. 10-2023-0128057, filed on Sep. 25, 2023, and all the benefits accruing therefrom under 35 U.S.C. § 119, the content of which in its entirety is herein incorporated by reference.

### BACKGROUND

The present disclosure herein relates to a display device and a manufacturing method thereof, and more particularly, to a display device including a pad electrode and a bump electrode.

An electronic apparatus that provides an image to a user, such as a smartphone, a digital camera, a laptop computer, a navigation system, and a smart television, includes a display device for displaying the image. The display device generates an image and provides the image to a user through a display screen.

The display device includes a display panel that displays the image. The display panel includes a plurality of gate lines, a plurality of data lines, and a plurality of pixels that are connected to the plurality of gate lines and the plurality of data lines.

The display panel may be connected to a driving part which provides electrical signals, for displaying images, to the gate lines or the data lines.

### SUMMARY

The present disclosure provides a display device with improved electrical connection characteristics between a pad electrode and a bump electrode.

The present disclosure also provides a manufacturing method of a display device with a simplified process.

An embodiment of the invention provides a display device including: a display panel including a display region in which a pixel is disposed, and a non-display region in which a pad electrode is disposed, a driving part disposed on the display panel, and having a bump electrode disposed to correspond to the pad electrode, and an adhesive layer in contact with the pad electrode and the bump electrode, where the pad electrode includes: a first connection pattern containing a conductive material; an auxiliary pattern disposed on the first connection pattern, protruding toward the bump electrode, and containing an insulating material; and a second connection pattern, which contains a conductive material, of which a portion is disposed on the auxiliary pattern, and in which an opening that exposes a portion of the auxiliary pattern is defined, and the auxiliary pattern includes a tip portion more protruding toward the opening than the first connection pattern.

In an embodiment, the auxiliary pattern and the first connection pattern may form an undercut shape on a cross-section.

In an embodiment, the pad electrode may include a connection part which is in contact with the bump electrode, and the opening may not overlap the connection part in a plan view.

In an embodiment, the opening may be provided in plurality, and the plurality of openings may be disposed apart from each other with the auxiliary pattern therebetween in the plan view.

In an embodiment, the auxiliary pattern may be provided in plurality, the opening may be provided in plurality, and the plurality of openings may one-to-one correspond to the plurality of auxiliary patterns.

In an embodiment, the opening may be provided in plurality, the auxiliary pattern may be provided in plurality, and the plurality of openings and the plurality of auxiliary patterns may be alternately disposed along a first direction.

In an embodiment, a side surface of the auxiliary pattern exposed by the opening may include a recessed insulation part which is recessed downwards.

In an embodiment, the adhesive layer may surround the tip portion and may bond the pad electrode and the bump electrode to each other.

In an embodiment, the first connection pattern may include a recessed conductive part which is more recessed toward a center of the auxiliary pattern than the auxiliary pattern in a plan view.

In an embodiment, the tip portion may more protrude toward the opening than the recessed conductive part by a first protruding length, and the first protruding length may be about 0.4 micrometers (μm) or more.

In an embodiment, the recessed conductive part may more protrude toward the opening than a side surface of the portion of the second connection pattern disposed on the auxiliary pattern among side surfaces of the second connection pattern, which define the opening on a cross-section.

In an embodiment, the second connection pattern may be in contact with the bump electrode.

In an embodiment, the display device may further include a signal line having a wire portion connected to the pixel and a pad portion extending from an end of the wire portion and having a larger width than a width of the wire portion, and an insulation layer disposed on the pad portion and covering the pad portion, and the second connection pattern may be electrically connected to the pad portion by a contact hole passing through the insulation layer.

In an embodiment, the contact hole may not overlap the auxiliary pattern in a plan view.

In an embodiment, the adhesive layer may not include a conductive material.

In an embodiment of the invention, a display device includes: a display panel having a pad electrode, a driving part disposed on the display panel, and having a bump electrode disposed to correspond to the pad electrode, and an adhesive layer in contact with the pad electrode and the bump electrode. The pad electrode includes: a first connection pattern containing a conductive material; an auxiliary pattern disposed on the first connection pattern, protruding toward the bump electrode, and containing an insulating material; and a second connection pattern, which contains a conductive material, of which a portion is disposed on the auxiliary pattern, and in which an opening that exposes a portion of the auxiliary pattern is defined, and the first connection pattern includes a recessed conductive part which is more recessed toward a center of the auxiliary pattern than the auxiliary pattern in a plan view.

In an embodiment of the invention, a manufacturing method of a display device includes: forming an auxiliary pattern, which protrudes upwards and contains an insulating material, on a preliminary first connection pattern containing a conductive material; forming a preliminary second connection pattern layer which covers the preliminary first connection pattern and the auxiliary pattern and contains a conductive material; performing first etching of the preliminary second connection pattern layer such that a second connection pattern is formed by forming an opening that exposes a portion of the auxiliary pattern in the preliminary second connection pattern layer; and performing second etching of the preliminary first connection pattern such that a first connection pattern including a recessed conductive part more recessed toward a center of the auxiliary pattern than the auxiliary pattern in a plan view is formed.

In an embodiment, the performing of the first etching may include: forming a photoresist pattern on the preliminary second connection pattern layer, and forming the second connection pattern by etching a portion of the preliminary second connection pattern layer not overlapping the photoresist pattern in the plan view, and in the performing of the second etching, the preliminary first connection pattern may be etched to form the first connection pattern in a state where the photoresist pattern remains.

In an embodiment, in the performing of the second etching, a recessed insulation part, which is recessed downwards, may be formed in a side surface of the auxiliary pattern exposed by the opening.

In an embodiment, the first connection pattern and the auxiliary pattern may form an undercut shape on a cross-section.

### BRIEF DESCRIPTION OF THE FIGURES

The accompanying drawings are included to provide a further understanding of the invention, and are incorporated in and constitute a part of this specification. The drawings illustrate embodiments of the invention and, together with the description, serve to explain principles of the invention. In the drawings:

FIG. 1 is a perspective view of an electronic apparatus according to an embodiment of the invention;

FIG. 2 is an exploded perspective view of an electronic apparatus according to an embodiment of the invention;

FIG. 3 is a cross-sectional view of a display device according to an embodiment of the invention;

FIG. 4 is a plan view of a display panel, illustrated in FIG. 3, according to an embodiment of the invention;

FIG. 5 is a cross-sectional view of a pixel according to an embodiment of the invention;

FIG. 6 is a drawing illustrating a bent state of a bending part of FIG. 4 according to an embodiment of the invention;

FIG. 7 is an enlarged perspective view of a pad region, illustrated in FIG. 4, according to an embodiment of the invention;

FIG. 8 is an enlarged plan view of a first pad electrode, illustrated in FIG. 7, according to an embodiment of the invention;

FIG. 9A is a cross-sectional view taken along line A-A′ of FIG. 8 according to an embodiment of the invention;

FIG. 9B is a cross-sectional view taken along line B-B′ of FIG. 8 according to an embodiment of the invention;

FIG. 9C is a cross-sectional view taken along line C-C′ of FIG. 8 according to an embodiment of the invention;

FIG. 10A is a cross-sectional view taken along line A-A′ of FIG. 8 after a first pad electrode and a first bump electrode, according to an embodiment of the invention, are bonded to each other;

FIG. 10B is a cross-sectional view taken along line B-B′ of FIG. 8 after a first pad electrode and a first bump electrode, according to an embodiment of the invention, are bonded to each other;

FIGS. 11A to 11F are plan views illustrating arrangements of an opening and an auxiliary pattern according to embodiments of the invention; and

FIGS. 12A to 12G are cross-sectional views illustrating some operations of a manufacturing method of a display device according to an embodiment of the invention.

### DETAILED DESCRIPTION

In this specification, it will be understood that when an element (or a region, a layer, a portion, or the like) is referred to as being “on”, “connected to”, “coupled to” another element, it may be directly disposed on, connected or coupled to the other element, or intervening elements may be disposed therebetween.

Like reference numerals or symbols refer to like elements throughout. In the drawings, the thickness, the ratio, and the size of the element are exaggerated for effective description of the technical contents. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the scope of the invention. Similarly, a second element, component, region, layer or section may be termed a first element, component, region, layer or section. As used herein, the singular forms, “a”, “an” and “the” are intended to include the plural forms as well, unless the context clearly indicates otherwise.

Also, terms of “below”, “on lower side”, “above”, “on upper side”, or the like may be used to describe the relationships of the elements illustrated in the drawings. These terms have relative concepts and are described on the basis of the directions indicated in the drawings.

It will be further understood that the terms “includes” and/or “have”, when used in this specification, specify the presence of stated features, integers, steps, operations, elements, components, and/or groups thereof, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within +10%, 5% or 2% of the stated value.

Hereinafter, embodiments of the invention are described with reference to the accompanying drawings.

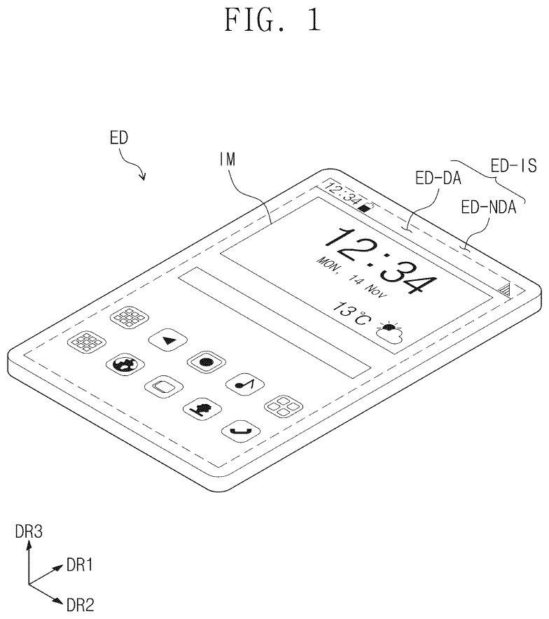

FIG. 1 is a perspective view of an electronic apparatus according to an embodiment of the invention.

Referring to FIG. 1, the electronic apparatus ED may have a rectangular shape including long sides extending in a first direction DR1 and short sides extending in a second direction DR2 crossing the first direction DR1. However, an embodiment of the invention is not limited thereto, and the electronic apparatus ED may have various shapes such as a circular and polygonal shapes.

Hereinafter, a direction substantially perpendicular to a plane defined by the first direction DR1 and the second direction DR2 is defined as a third direction DR3. In addition, in this specification, “in a plan view” may be defined as a state when viewed from the third direction DR3 (i.e., thickness direction of the display panel DP).

An upper surface of the electronic apparatus ED may be defined as a display surface ED-IS, and the display surface ED-IS may have a flat surface defined by the first direction DR1 and the second direction DR2. Images IM generated in the electronic apparatus ED may be provided to a user through the display surface ED-IS.

The display surface ED-IS may include a display region ED-DA and a non-display region ED-NDA around the display region ED-DA. The display region ED-DA may display an image, and the non-display region ED-NDA may not display an image. The non-display region ED-NDA may surround the display region ED-DA, and may define a border of the electronic apparatus ED which is printed in a predetermined color.

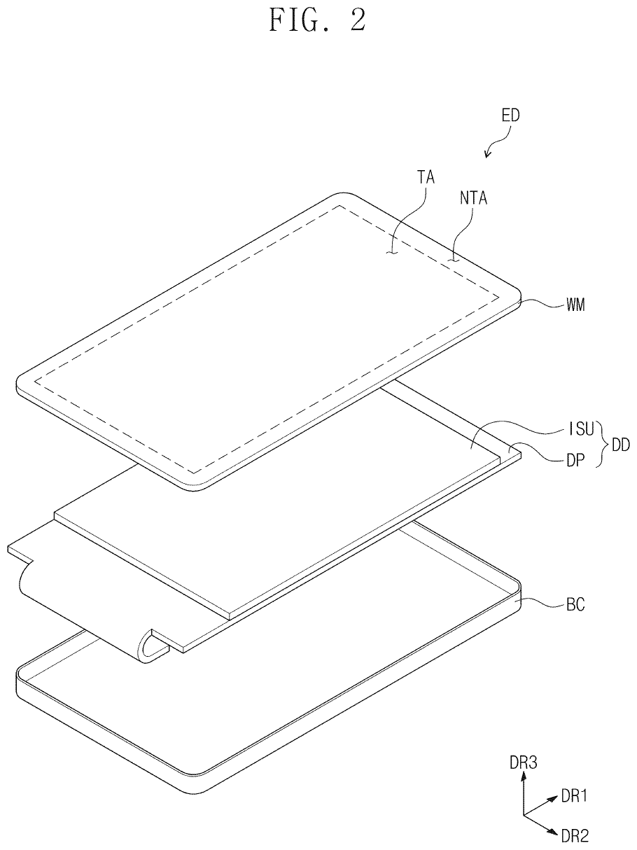

FIG. 2 is an exploded perspective view of an electronic apparatus according to an embodiment of the invention.

Referring to FIG. 2, the electronic apparatus ED may include a window WM, a display device DD, and a housing BC. The housing BC may accommodate the display device DD, and may be coupled to the window WM. Although not illustrated in the drawing, the electronic apparatus ED may further include other electronic modules that are accommodated in the housing BC and electrically connected to a display panel DP. For example, the electronic apparatus ED may further include a main board, a circuit module mounted on the main board, a camera module, a power module, etc.

The window WM may be disposed above the display device DD. The window WM may transmit an image, provided from the display device DD, to the outside. The window WM may include a transmission region TA and a non-transmission region NTA. The transmission region TA may overlap the display region ED-DA in FIG. 1. The transmission region TA may have a shape corresponding to the shape of a display region ED-DA.

The non-transmission region NTA may overlap the non-display region ED-NDA (see FIG. 1), and may have a shape corresponding to the shape of the non-display region ED-NDA (see FIG. 1). The non-transmission region NTA may be a region having a relatively lower light transmittance than the light transmittance of the transmission region TA.

The display device DD may generate an image and detect an external input. The display device DD may include a display panel DP and an input sensor ISU. Although not illustrated in the drawing, the display device DD may further include an anti-reflection member disposed on the input sensor ISU. The anti-reflection member may include a polarizer and a retarder, or include a color filter and a black matrix.

The display panel DP may be an emission-type display panel, and the type may not be particularly limited. For example, the display panel DP may be an organic light-emitting display panel or an inorganic light-emitting display panel. A light-emitting layer of the organic light-emitting display panel may include an organic light-emitting material. A light-emitting layer of the inorganic light-emitting display panel may include quantum dots, quantum rods, a nano-LED, etc. Hereinafter, the display panel DP is described as the organic light-emitting display panel.

The input sensor ISU may include any one among a capacitance-type sensor, an optical sensor, an ultrasonic sensor, and an electromagnetic induction sensor. The input sensor ISU may be disposed on the display panel DP through a continuous process, or may be separately manufactured and then adhered to an upper side of the display panel DP through an adhesive layer.

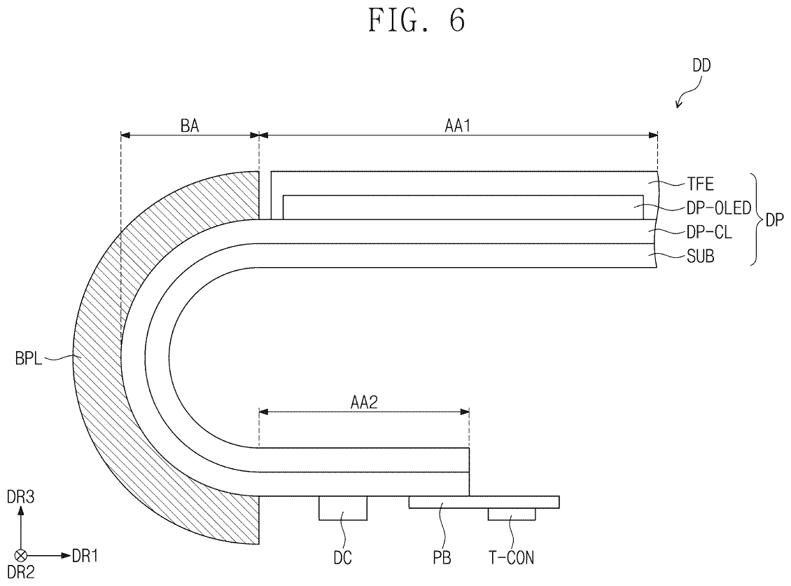

A portion of the display panel DP may be bent such that a driving part DC (see FIG. 6) faces downwards. The non-display region ED-NDA (see FIG. 1) of the display panel DP may be bent. However, the portion to be bent is not limited thereto, and a circuit board PB (see FIG. 6), not the display panel DP, may be bent in another embodiment.

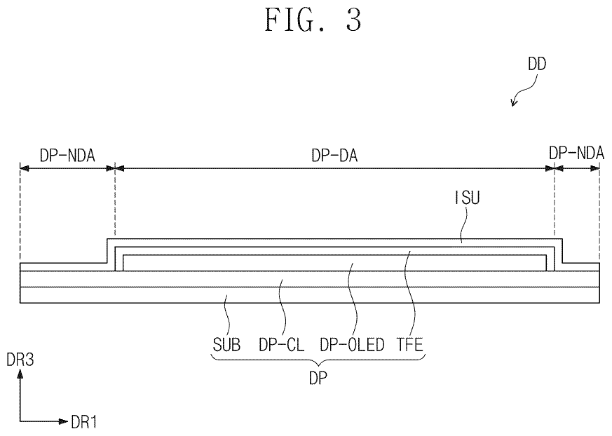

FIG. 3 is a cross-sectional view of a display device according to an embodiment of the invention.

Referring to FIG. 3, a display panel DP may include a substrate SUB, a circuit element layer DP-CL disposed on the substrate SUB, a display element layer DP-OLED, and a thin-film encapsulation layer TFE. The input sensor ISU may be disposed on the thin-film encapsulation layer TFE.

The substrate SUB may include a display region DP-DA and a non-display region DP-NDA around the display region DP-DA. The substrate SUB may include a flexible plastic material such as glass or polyimide (“PI”). The display element layer DP-OLED may be disposed on the display region DP-DA.

A plurality of pixels may be disposed on the circuit element layer DP-CL and the display element layer DP-OLED. Although not illustrated in the drawing, the pixels may each include a plurality of transistors and at least one capacitor disposed on the circuit element layer DP-CL, and a light-emitting element disposed on the display element layer DP-OLED to be connected to the transistor.

The thin-film encapsulation layer TFE may be disposed on the circuit element layer DP-CL to cover the display element layer DP-OLED. The thin-film encapsulation layer TFE may protect the pixels from moisture, oxygen, and foreign substances.

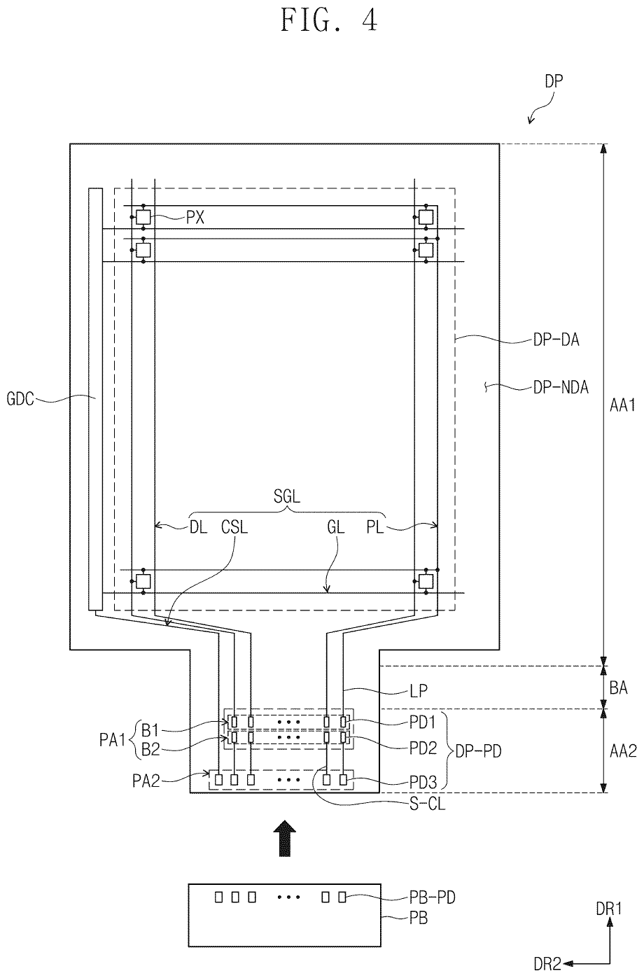

FIG. 4 is a plan view of the display panel DP illustrated in FIG. 3.

Referring to FIG. 4, the display panel DP may include a plurality of pixels PX, a gate driving circuit GDC, a plurality of signal lines SGL, and a plurality of signal pads DP-PD.

The display panel DP may include a first part AA1, a second part AA2, and a bending part BA disposed between the first part AA1 and the second part AA2. The first part AA1, the bending part BA, and the second part AA2 may be arranged in a first direction DR1, and the bending part BA may extend in a second direction DR2. The bending part BA may extend from the first part AA1 in the first direction DR1, and the second part AA2 may extend from the bending part BA in the first direction DR1.

The first part AA1 may have long sides extending in the first direction DR1 and opposed to each other in the second direction DR2. With respect to the second direction DR2, the length of each of the bending part BA and the second part AA2 may be smaller than the length of the first part AA1.

The pixels PX may be disposed in the display region DP-DA. Each of the pixels PX includes an organic light-emitting element and a pixel driving circuit connected thereto. The gate driving circuit GDC sequentially outputs gate signals to a plurality of gate lines GL to be described later. A transistor of the gate driving circuit GDC may be formed through the same process as the process through which a transistor of the pixel PX is formed, for example, a low temperature polycrystalline silicon (“LTPS”) process or a low temperature polycrystalline oxide (“LTPO”) process. The display panel DP may also further include another driving circuit that provides an emission control signal to the pixels PX.

The signal lines SGL may include gate lines GL, data lines DL, a power line PL, and a control signal line CSL. The gate lines GL may each be connected to a corresponding pixel PX among the pixels PX, and the data lines DL may each be connected to a corresponding pixel PX among the pixels PX. The power line PL may be connected to the pixels PX. The control signal line CSL may provide control signals to a scan driving circuit.

The signal lines SGL may overlap the display region DP-DA and the non-display region DP-NDA. The signal lines SGL may each include a wire portion LP. The wire portion LP may overlap the display region DP-DA and the non-display region DP-NDA.

A plurality of signal pads DP-PD may be disposed in the second part AA2 of the non-display region DP-NDA. First pad electrodes PD1, second pad electrodes PD2, and third pad electrodes PD3 may be included. A region where the first and second pad electrodes PD1 and PD2 are disposed may be defined as a first pad region PA1, and a region where the third pad electrodes PD3 are disposed may be defined as a second pad region PA2.

The first pad region PA1 may be a region overlapping a driving part DC (see FIG. 6) in FIG. 6, and the second pad region PA2 may be a region overlapping a circuit board PB in a plan view. The first pad region PA1 may include a first region B1 where the first pad electrodes PD1 are disposed, and a second region B2 where the second pad electrodes PD2 are disposed. The first pad region PA1 and the second pad region PA2 may be disposed in the non-display region DP-NDA. The first pad region PA1 and the second pad region PA2 may be spaced apart from each other in the first direction DR1.

The first pad electrodes PD1 may each be connected to a corresponding data line DL among the data lines DL. Although not illustrated in the drawing, the first pad electrodes PD1 and the second pad electrodes PD2 may be electrically connected to each other. The second pad electrodes PD2 may be connected to the third pad electrodes PD3 through connection signal lines S-CL.

The circuit board PB may include a plurality of circuit pads PB-PD. The circuit pads PB-PD may be arranged in the second direction DR2. The circuit pads PB-PD of the circuit board PB may be in contact with the third pad electrodes PD3 in the second pad region PA2 to be connected thereto.

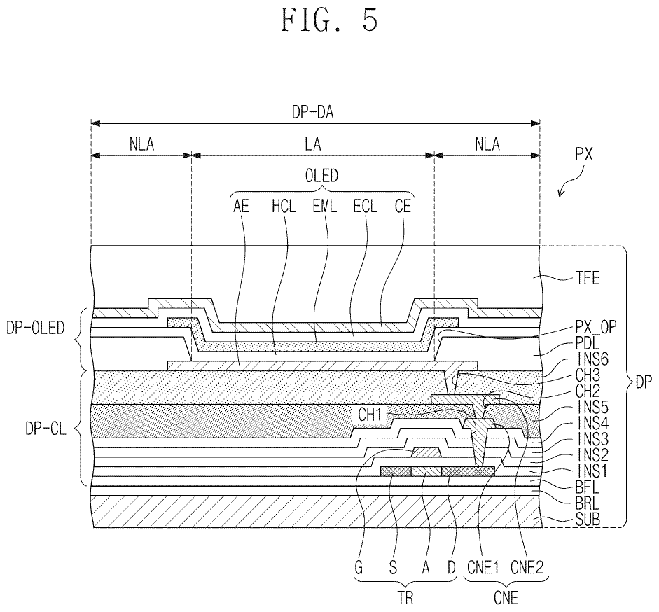

FIG. 5 is a cross-sectional view of a pixel according to an embodiment of the invention.

Referring to FIGS. 4 and 5, the pixel PX may include a transistor TR and a light-emitting element OLED. The light-emitting element OLED may include a first electrode AE (or anode), a second electrode CE (or cathode), a hole control layer HCL, an electron control layer ECL, and a light-emitting layer EML.

The transistor TR and the light-emitting element OLED may be disposed on a substrate SUB. One transistor TR is exemplarily illustrated, but substantially, the pixel PX may include a plurality of transistors and at least one capacitor for driving the light-emitting element OLED. The plurality of transistors and the at least one capacitor may be connected to each other.

The display region DP-DA may include a light-emitting region LA and a non-light-emitting region NLA, around the light-emitting region LA, corresponding to each of the pixels PX. The light-emitting element OLED may be disposed in the light-emitting region LA.

The substrate SUB may include polyimide (PI) as a flexible plastic material. A barrier layer BRL may be disposed on the substrate SUB. A buffer layer BFL may be disposed on the barrier layer BRL. The barrier layer BRL and the buffer layer BFL may be inorganic layers.

A semiconductor pattern may be disposed on the buffer layer BFL. The semiconductor pattern may include polysilicon, amorphous silicon, or metal oxide. The semiconductor pattern may be doped with an N-type dopant or a P-type dopant. The semiconductor pattern may include a region doped with high concentration and a region doped with low concentration. The region with high concentration may have a higher conductivity than the region with low concentration, and substantially serve as a source electrode and a drain electrode of the transistor TR. The region doped with low concentration may substantially correspond to an active (or channel) of the transistor.

A source S, an active A, and a drain D of the transistor TR may be formed from the semiconductor pattern. A first insulation layer INS1 may be disposed on the semiconductor pattern. A gate G of the transistor TR may be disposed on the first insulation layer INS1. A second insulation layer INS2 may be disposed on the gate G. A third insulation layer INS3 may be disposed on the second insulation layer INS2. A fourth insulation layer INS4 may be disposed on the third insulation layer INS3.

A connection electrode CNE may include a first connection electrode CNE1 and a second connection electrode CNE2 in order to connect the transistor TR and the light-emitting element OLED to each other. The first connection electrode CNE1 may be disposed on the fourth insulation layer INS4, and connected to the drain D through a first contact hole CH1 defined in the first to fourth insulation layers INS1 to INS4.

A fifth insulation layer INS5 may be disposed on the fourth insulation layer INS4. The second connection electrode CNE2 may be disposed on the fifth insulation layer INS5. The second connection electrode CNE2 may be connected to the first connection electrode CNE1 through a second contact hole CH2 defined in the fifth insulation layers INS5. The second connection electrode CNE2 may be the data line DL in FIG. 4.

A sixth insulation layer INS6 may be disposed on the second connection electrode CNE2. The layers including from the buffer layer BFL to the sixth insulation layer INS6 may be defined as a circuit element layer DP-CL. The first insulation layer INS1 through the sixth insulation layer INS6 may be inorganic layers or organic layers.

A first electrode AE may be disposed on the sixth insulation layer INS6. The first electrode AE may be connected to the second connection electrode CNE2 through a third contact hole CH3 defined in the sixth insulation layer INS6. The first electrode AE may be connected to the transistor TR through the first and second connection electrodes CNE1 and CNE2. A pixel-defining film PDL, in which an opening PX_OP is defined to expose a predetermined portion of the first electrode AE, may be disposed on the first electrode AE and the sixth insulation layer INS6.

The hole control layer HCL may be disposed on the first electrode AE and the pixel-defining film PDL. The hole control layer HCL may include a hole transport layer and a hole injection layer.

The light-emitting layer EML may be disposed on the hole control layer HCL. The light-emitting layer EML may be disposed in a region corresponding to the opening PX_OP. The light-emitting layer EML may include an organic material and/or an inorganic material. The light-emitting layer EML may generate light of any one color among the red, green, and blue colors.

The electron control layer ECL may be disposed on the light-emitting layer EML and the hole control layer HCL. The electron control layer ECL may include an electron transport layer and an electron injection layer. The hole control layer HCL and the electron control layer ECL may be disposed in the light-emitting region LA and the non-light-emitting region NLA in common.

A second electrode CE may be disposed on the electron control layer ECL. The second electrode CE may be disposed in the pixels PX in common. A layer on which the light-emitting element OLED is disposed may be defined as a display element layer DP-OLED.

The thin-film encapsulation layer TFE may be disposed on the second electrode CE to cover the pixel PX (see FIG. 4). Although not illustrated in the drawing, the thin-film encapsulation layer TFE may be composed of a plurality of layers. Some layers, among the plurality of layers, may include inorganic insulation layers, and may protect the pixel PX (see FIG. 4) from moisture/oxygen. Other layers may include organic insulation layers, and may protect the pixel PX (see FIG. 4) from foreign substances such as dust particles.

A first voltage may be applied to the first electrode AE through the transistor TR, and a second voltage, the level of which is lower than the level of the first voltage, may be applied to the second electrode CE. Holes and electrons, injected to the light-emitting layer EML, combine to form excitons, and the excitons transition to the ground state, so that the light-emitting element OLED may emit light.

FIG. 6 is a drawing illustrating a bent state of a bending part in FIG. 4 according to an embodiment of the invention.

FIG. 6 exemplarily illustrates a side view of a display device DD when viewed from a second direction DR2.

Since a substrate SUB, a circuit element layer DP-CL, a display element layer DP-OLED, and a thin-film encapsulation layer TFE in FIG. 6 are the same as the substrate SUB, the circuit element layer DP-CL, the display element layer DP-OLED, and the thin-film encapsulation layer TFE in FIG. 5, respectively, the descriptions thereof will be omitted or simplified.

The display device DD may include a driving part DC, a circuit board PB, a bending protection layer BPL, and a timing controller T-CON.

The driving part DC may be disposed on a display panel DP, and mounted on the display panel DP. However, an embodiment of the invention is not limited thereto. The driving part DC may generate a driving signal for an operation of the display panel DP on the basis of a control signal transmitted from the circuit board PB.

The circuit board PB may be disposed on one end of the substrate SUB, and electrically connected to the circuit element layer DP-CL. The timing controller T-CON may be disposed on the circuit board PB. The timing controller T-CON may be formed as an integrated circuit chip to be mounted on an upper surface of the circuit board PB.

The bending part BA may be bent such that a second part AA2 is disposed under a first part AA1. Therefore, the driving part DC, the circuit board PB, and the timing controller T-CON may be disposed under the second part AA2.

The bending protection layer BPL may be disposed on the bending part BA. The bending protection layer BPL may be adjacent to borders of the first and second parts AA1 and AA2. The bending protection layer BPL may be disposed apart from the thin-film encapsulation layer in a first direction DR1. The bending protection layer BPL may be bent together with the bending part BA when the display panel DP is bent.

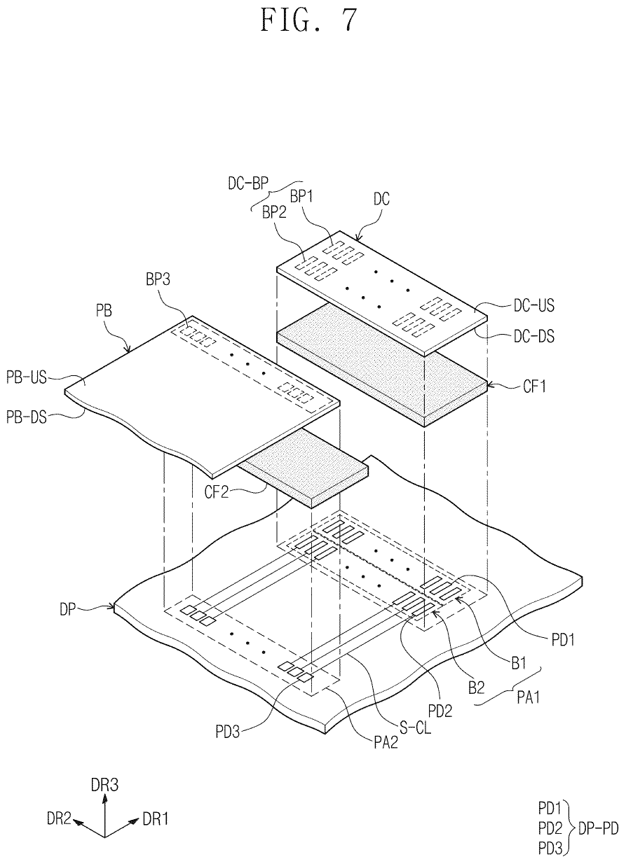

FIG. 7 is an enlarged perspective view of the pad region, illustrated in FIG. 4, according to an embodiment of the invention.

FIG. 7 exemplarily illustrates a driving part DC and a circuit board PB separately from a display panel DP.

Since first pad electrodes PD1, second pad electrodes PD2, connection signal lines S-CL, and third pad electrodes PD3 in FIG. 7 are the same as the first pad electrodes PD1, the second pad electrodes PD2, the connection signal lines S-CL, and the third pad electrodes PD3 in FIG. 4, respectively, the descriptions thereof will be omitted or simplified.

Referring to FIGS. 4 and 7, the driving part DC may be bonded to a first pad region PA1 through a first adhesive layer CF1. The circuit board PB may be bonded to a second pad region PA2 through a second adhesive layer CF2. The first and second adhesive layers CF1 and CF2 may include a synthetic resin having adhesiveness.

When the first adhesive layer CF1 hardens, the first and second pad electrodes PD1 and PD2 and bump electrodes DC-BP may be fixed in a contact state. When the second adhesive layer CF2 hardens, the third pad electrodes PD3 and third bump electrodes BP3 may be fixed in a contact state.

The driving part DC may be disposed on the first and second pad electrodes PD1 and PD2. The driving part DC may include an upper surface DC-US and a lower surface DC-DS. The lower surface DC-DS of the driving part DC may be a surface facing the first and second pad electrodes PD1 and PD2. The driving part DC may include the bump electrodes DC-BP that are electrically connected to the first pad electrodes PD1 disposed on the substrate SUB. The bump electrodes DC-BP may be disposed on the lower surface DC-DS of the driving part DC. The bump electrodes DC-BP may be disposed to correspond to the pad electrodes PD1 and PD2.

The bump electrodes DC-BP may include first bump electrodes BP1 and second bump electrodes BP2. The first bump electrodes BP1 and the second bump electrodes BP2 may be spaced apart from each other in a first direction DR1. The first bump electrodes BP1 may be arranged in a second direction DR2. The second bump electrodes BP2 may be arranged in a second direction DR2. Although not illustrated in the drawing, the first bump electrodes BP1 and the second bump electrodes BP2 may have a shape protruding from the lower surface DC-DS of the driving part DC to be exposed to the outside.

When the driving part DC moves in a third direction DR3, the first bump electrodes BP1 may be in contact with the first pad electrodes PD1 to be electrically connected thereto, and the second bump electrodes BP2 may be in contact with the second pad electrodes PD2 to be electrically connected thereto.

Although not illustrated in the drawing, the driving part DC may include an integrated circuit. The integrated circuit may be disposed on the bump electrodes DC-BP. The integrated circuit may be connected to the bump electrodes DC-BP. The driving part DC may receive first signals from the outside through the second pad electrodes PD2 and the second bump electrodes BP2. The driving part DC may provide second signals, generated on the basis of signals, to the first pad electrodes PD1 through the first bump electrodes BP1. The first signal may be an image signal which is a digital signal applied from the outside, and the second signal may be a data signal which is an analog signal. The driving part DC may generate an analog voltage corresponding to a grayscale value of the image signal. The data signal may be provided to the pixel PX through the data line DL illustrated in FIG. 4.

The circuit board PB may be disposed on the display panel DP. The circuit board PB may be disposed on the third pad electrodes PD3. The circuit board PB may include an upper surface PB-US and a lower surface PB-DS. The lower surface PB-DS of the circuit board PB may be a surface facing the third pad electrodes PD3. The circuit board PB may include a plurality of third bump electrodes BP3 electrically connected to the third pad electrodes PD3. The third bump electrodes BP3 may be disposed on the upper surface PB-US of the circuit board PB. The third bump electrodes BP3 may be arranged in the second direction DR2. The circuit board PB may provide an image signal, a driving voltage, and other control signals to the driving part DC.

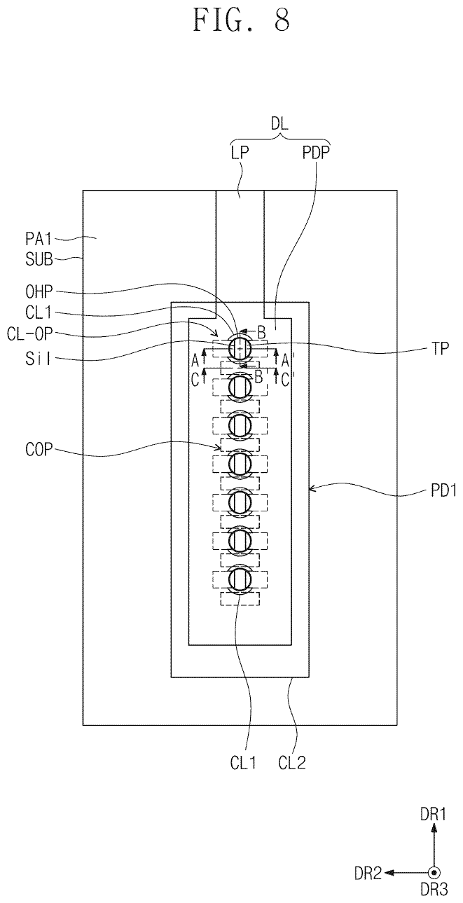

FIG. 8 is an enlarged plan view of the first pad electrode, illustrated in FIG. 7, according to an embodiment of the invention.

FIG. 8 exemplarily illustrates the first pad electrode PD1 disposed in a first pad region PA1, but a second pad electrode PD2 and a third pad electrode PD3 may include the same configuration as the first pad electrode PD1. In addition, FIG. 8 exemplarily illustrates a data line DL, but an embodiment of the invention is not limited thereto, and other signal lines SGL illustrated in FIG. 4 may be included.

Referring to FIGS. 4 and 8, the data lines DL may include wire portions LP and pad portions PDP. The wire portions LP may each be connected to a corresponding pixel PX among the pixels PX. The wire portions LP may each extend in a first direction DR1 to be connected to a corresponding signal pad DP-PD among the signal pads DP-PD. Hereinafter, any one data line DL will be described.

The pad portion PDP may extend from an end of the wire portion LP in the first direction DR1. Although not illustrated in the drawing, the pad portion PDP and the wire portion LP of the data line DL may be disposed on different layers and connected to each other. The width of the pad portion PDP may be larger than the width of the wire portion LP in a second direction DR2.

The signal pad DP-PD may be disposed on a substrate SUB. The signal pad DP-PD may be disposed on the pad portion PDP. For example, among the signal pads DP-PD, the first pad electrode PD1 is illustrated. The first pad electrode PD1 may include a first connection pattern CL1 and a second connection pattern CL2. For example, the first connection pattern CL1 and the second connection pattern CL2 may be the first connection electrode CNE1 and the second connection electrode CNE2 in FIG. 5, respectively.

In a plan view, the first and second connection patterns CL1 and CL2 may overlap the pad portion PDP. The first and second connection patterns CL1 and CL2 are exemplarily illustrated, but any one of the electrodes may be omitted, or an additional electrode may further be disposed.

The first pad electrode PD1 may include an auxiliary pattern OHP, the first connection pattern CL1, and the second connection pattern CL2. The first pad electrode PD1 may include a plurality of auxiliary patterns OHP. FIG. 8 illustrates the auxiliary patterns OHP as circles in a plan view, but an embodiment of the invention is not limited thereto, and the auxiliary patterns OHP may have various shapes. For example, the auxiliary patterns OHP may have polygonal shapes such as a triangular and quadrilateral shapes in a plan view.

The auxiliary pattern OHP may include a tip portion TP more protruding toward an opening CL-OP than the first connection pattern CL1 and overlapping the opening CL-OP in a plan view. A portion of the auxiliary pattern OHP except the tip portion TP may overlap the first connection pattern CL1 in a plan view.

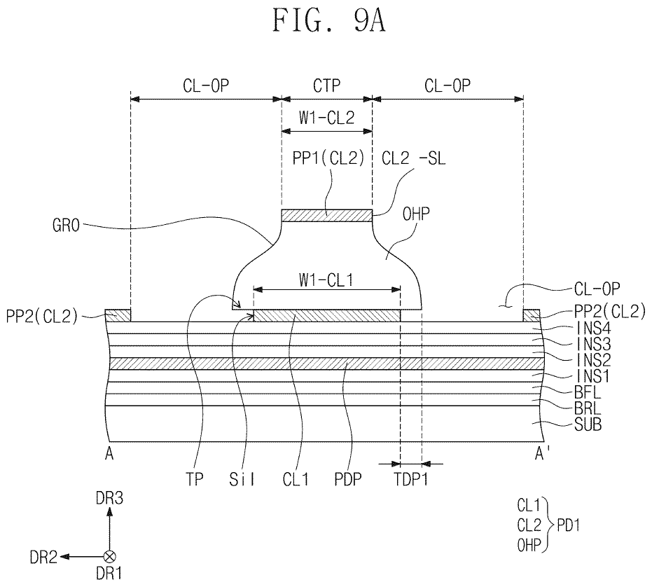

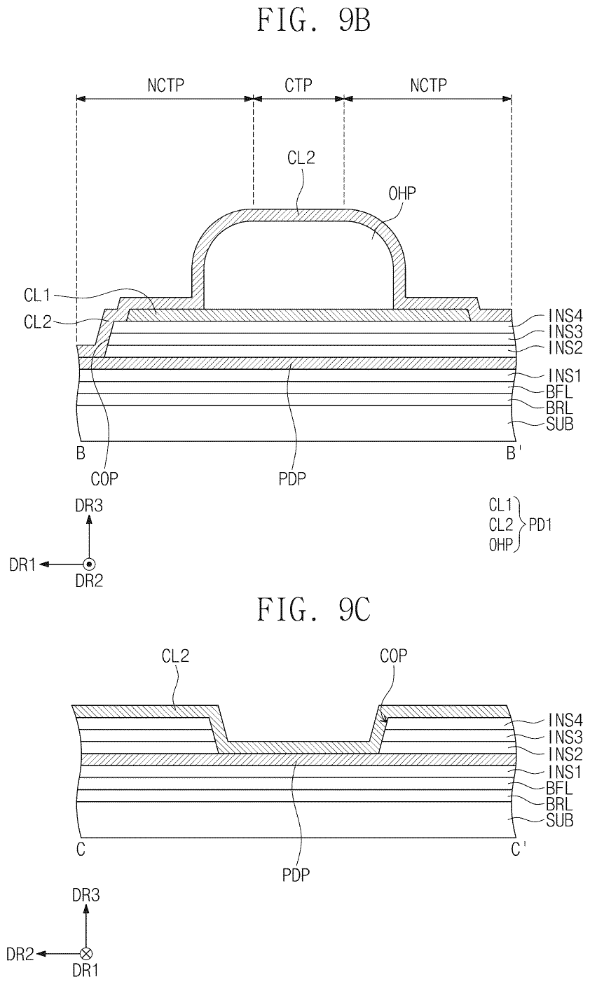

The shape of the tip portion TP will be described later with reference to FIG. 9A. The auxiliary pattern OHP may be provided in plurality and arranged along the first direction DR1. However, the arrangement of the auxiliary patterns OHP herein is an example, and may be changed. For example, the auxiliary patterns OHP may be disposed in multiple rows and columns. In addition, FIG. 8 illustrates that the centers of the auxiliary patterns OHP are disposed in a straight line along the first direction DR1, but the arrangement of the centers of the auxiliary patterns OHP is not limited thereto.

The first pad electrode PD1 may include the first connection pattern CL1. The first connection pattern CL1 may include a recessed conductive part Sil that is more recessed toward the center of the auxiliary pattern OHP than the auxiliary pattern OHP in a plan view. The tip portion TP of the auxiliary pattern OHP may cover the recessed conductive part Sil of the first connection pattern CL1 in a plan view.

The first connection pattern CL1 may have a shape in which the recessed conductive part Sil, recessed toward the center of the auxiliary pattern OHP, is defined on a side surface of a circle that covers the auxiliary pattern OHP in a plan view. A planar shape of the recessed conductive part Sil may correspond to a planar shape of the opening CL-OP. As used herein, the “planar shape” is a shape in a plan view. However, the shape of the first connection pattern CL1 herein is not limited thereto, and the first connection pattern CL1 may have various shapes. For another example, in a case where the planar shape of the auxiliary pattern OHP is a quadrangle, the first connection pattern CL1 may have a shape in which the recessed conductive part Sil, recessed toward the center of the auxiliary pattern OHP, is defined on a side surface of a quadrangle that covers the auxiliary pattern OHP in a plan view.

An outer side surface of a portion of the first connection pattern CL1 except the recessed conductive part Sil may be disposed farther from the center of the auxiliary pattern OHP than an outer side surface of the auxiliary pattern OHP. The first connection pattern CL1 may be provided in plurality, and the first connection patterns CL1 may overlap the auxiliary patterns OHP in a plan view, respectively. The first connection patterns CL1 may one-to-one correspond to the auxiliary patterns OHP. That is, the first connection patterns CL1 may correspond to the auxiliary patterns OHP, respectively. However, the shape and the arrangement of the first connection pattern CL1 may be changed. For example, one first connection pattern CL1 may have a shape in which the recessed conductive part Sil is defined on a side surface of a shape covering a plurality of auxiliary patterns OHP.

The second connection pattern CL2 may have a shape covering the pad portion PDP except the openings CL-OP in a plan view. The opening CL-OP overlapping a portion of the auxiliary pattern OHP in a plan view may be defined in the second connection pattern CL2. A portion (i.e., first conductive portion PP1 in FIG. 9A) of the second connection pattern CL2 may be disposed on the auxiliary pattern OHP, and the opening CL-OP may expose the portion of the auxiliary pattern OHP. This will be described later with reference to FIG. 9A.

The opening CL-OP may be provided in plurality, and the plurality of openings CL-OP may be disposed apart from each other with the auxiliary pattern OHP therebetween in a plan view. FIG. 8 exemplarily illustrates that the opening CL-OP has a quadrilateral shape, but the shape of the opening CL-OP may be formed in various shapes such as a polygonal and oval shapes in a plan view.

A contact hole COP may be disposed inside the second connection pattern CL2 in a plan view. The contact hole COP may be disposed between the auxiliary patterns OHP in a plan view. The contact hole COP may not overlap the auxiliary pattern OHP in a plan view. The second connection pattern CL2 and the pad portion PDP may be electrically connected to each other by the contact hole COP. The contact hole COP may pass through second to fourth insulation layers INS2 to INS4 (see FIG. 9C) which are disposed on the pad portion PDP and cover the pad portion PDP. This will be described later with reference to FIG. 9C.

FIG. 9A is a cross-sectional view taken along line A-A′ of FIG. 8 according to an embodiment of the invention. Since a substrate SUB, a barrier layer BRL, a buffer layer BFL, a first insulation layer INS1, a second insulation layer INS2, a third insulation layer INS3, and a fourth insulation layer INS4 in FIG. 9A are the same as the substrate SUB, the barrier layer BRL, the buffer layer BFL, the first insulation layer INS1, the second insulation layer INS2, the third insulation layer INS3, and the fourth insulation layer INS4 in FIG. 5, respectively, the descriptions thereof will be omitted or simplified.

Referring to FIG. 9A, a pad portion PDP may be disposed on the first insulation layer INS1. The pad portion PDP may include the same material as the gate G in FIG. 5, and may be formed through the same process as the process through which the gate G is formed. The second insulation layer INS2 may be disposed on the pad portion PDP to cover the pad portion PDP. The second insulation layer INS2 may be disposed on the first insulation layer INS1. The third insulation layer INS3 may be disposed on the second insulation layer INS2. The fourth insulation layer INS4 may be disposed on the third insulation layer INS3.

A first connection pattern CL1 may be disposed on the fourth insulation layer INS4. The first connection pattern CL1 may be disposed between the fourth insulation layer INS4 and an auxiliary pattern OHP. An upper surface of the first connection pattern CL1 may be in contact with a lower surface of the auxiliary pattern OHP. The first connection pattern CL1 may include a recessed conductive part Sil. The recessed conductive part Sil may be a portion of the first connection pattern CL1 (see FIG. 8) in FIG. 8 which is recessed in a direction parallel to the plane defined by the first and second directions DR1 and DR2 in a plan view. The recessed conductive part Sil may be more adjacent to the center of the first connection pattern CL1 than a tip portion TP in a plan view. An outer side surface of the first connection pattern CL1 that defines the recessed conductive part Sil may be more adjacent to the center of the first connection pattern CL1 than an outer side surface of the tip portion TP in a plan view. The first connection pattern CL1 may include a conductive material.

On a cross-section, the recessed conductive part Sil may more protrude toward an opening CL-OP than an inner side surface CL2-SL of the first conductive portion PP1 overlapping the auxiliary pattern OHP among inner side surfaces of the second connection pattern CL2 defining the opening CL-OP. As used herein, “on a cross-section” is a cross-sectional view cut by a plane parallel to the third direction DR3. A width W1-CL2 of the second connection pattern CL2 overlapping the auxiliary pattern OHP on a cross-section may be smaller than a width W1-CL1 of the first connection pattern CL1 overlapping the auxiliary pattern OHP on a cross-section.

The auxiliary pattern OHP and the first connection pattern CL1 may form an undercut shape on a cross-section together. A step may be defined on the boundary between the auxiliary pattern OHP and the first connection pattern CL1. The first connection pattern CL1, disposed under the auxiliary pattern OHP, may be more etched toward the center of the first connection pattern CL1 than the auxiliary pattern OHP, thereby forming the undercut shape.

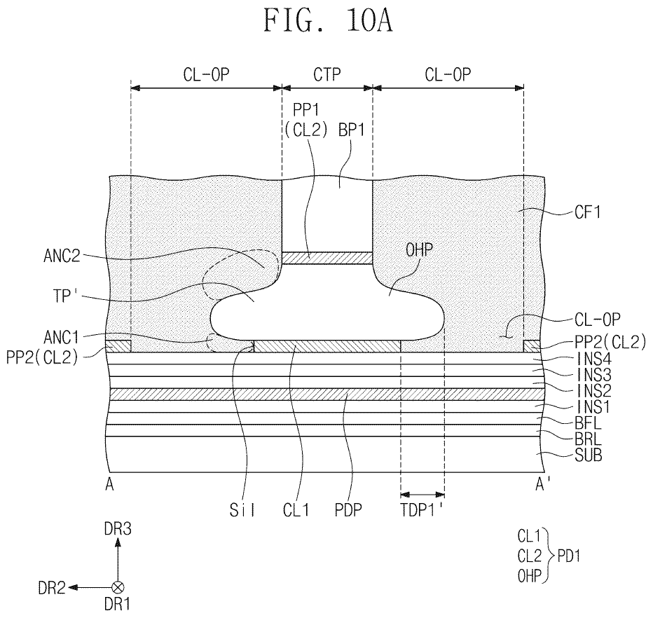

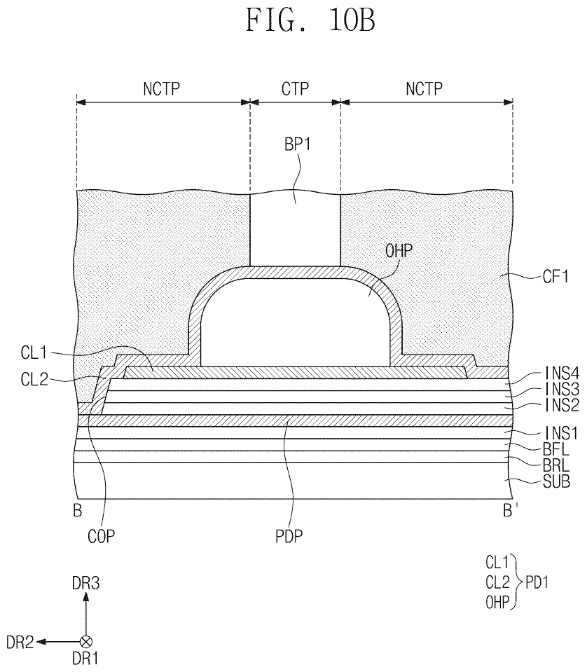

The auxiliary pattern OHP may be disposed on the first connection pattern CL1. The auxiliary pattern OHP may protrude in a third direction DR3. The auxiliary pattern OHP may protrude toward a first bump electrode BP1 (see FIG. 10A). The auxiliary pattern OHP may overlap the pad portion PDP in a plan view.

The auxiliary pattern OHP may include the tip portion TP more protruding toward the opening CL-OP than the first connection pattern CL1. The tip portion TP may protrude more than opposite side surfaces of the first connection pattern CL1 in a second direction DR2 or the opposite direction of the second direction DR2. The tip portion TP may more protrude toward the opening CL-OP than the recessed conductive part Sil by a first protruding length TDP1.

The first protruding length TDP1 may be about 0.4 μm or more. When the first protruding length TDP1 is less than about 0.4 μm, a first adhesive layer CF1 (see FIG. 10A) surrounding the tip portion TP may not fix the auxiliary pattern OHP properly. Accordingly, after a first pad electrode PD1 and a first bump electrode BP1 (see FIG. 10A) are bonded to each other, electrical connection characteristics between the first pad electrode PD1 and the first bump electrode BP1 (see FIG. 10A) may deteriorate. This will be described later in more detail with reference to FIG. 10A.

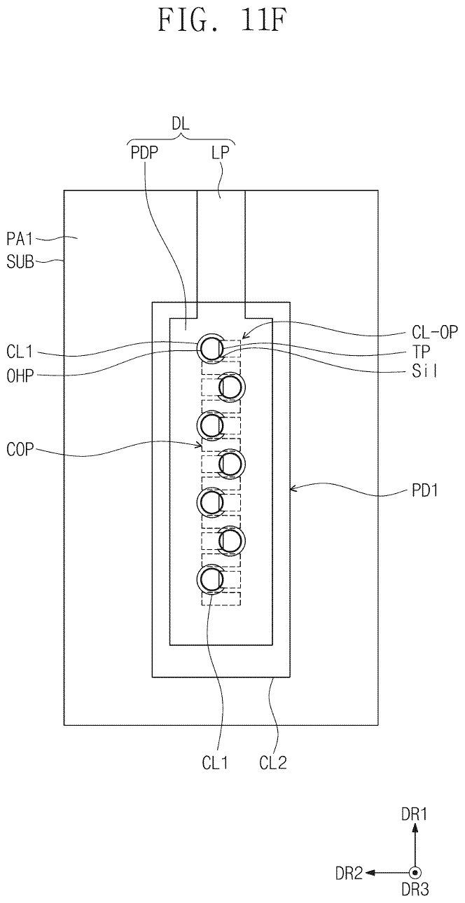

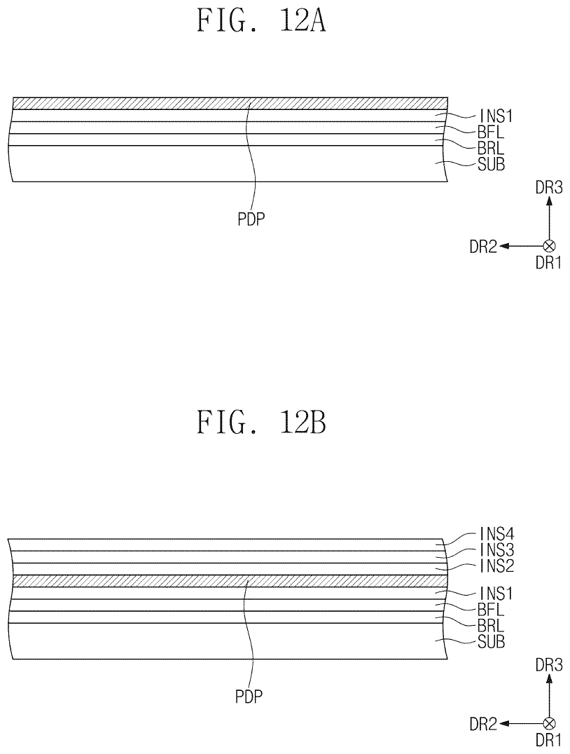

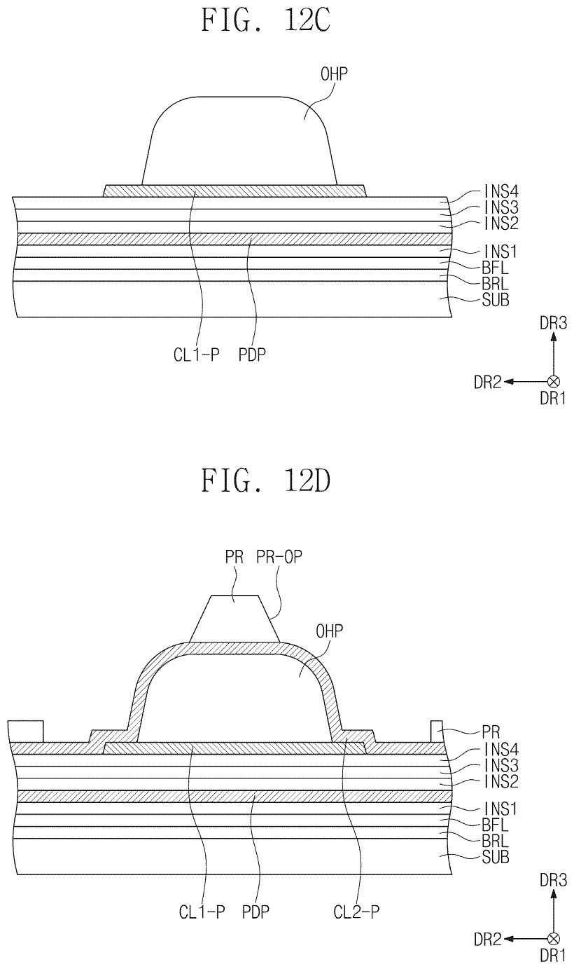

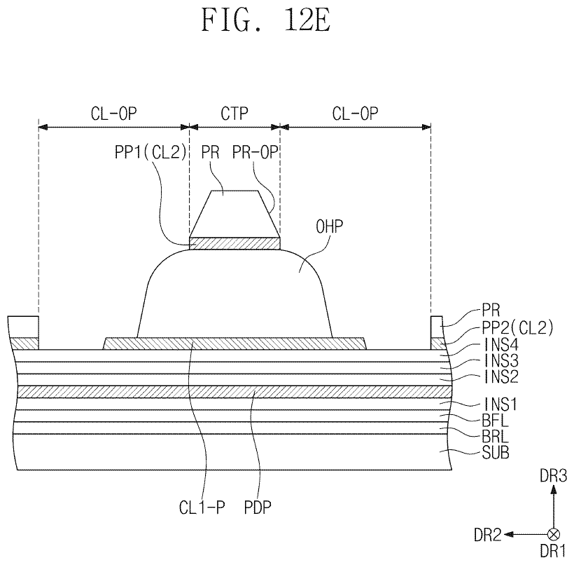

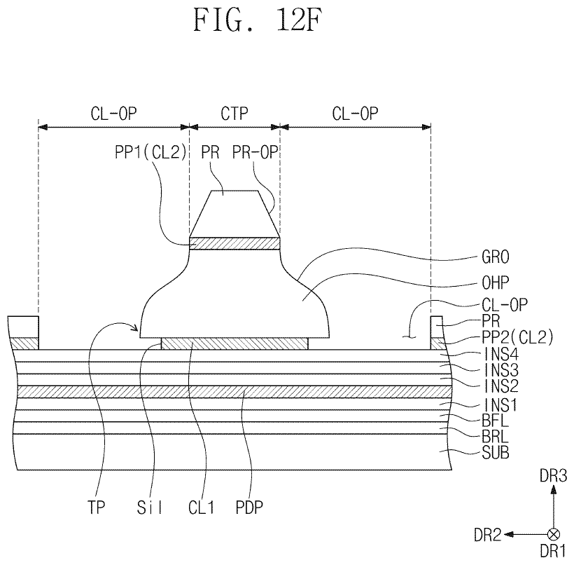

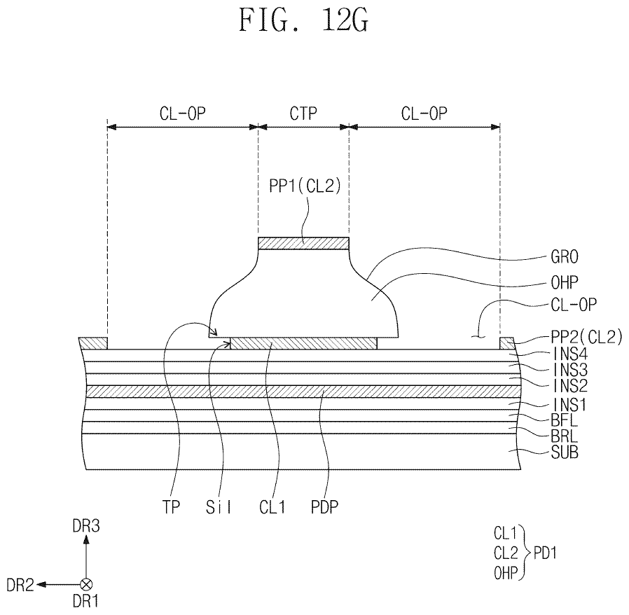

An side surface of the auxiliary pattern OHP may include a recessed insulation part GR0 that is recessed downwards. The recessed insulation part GR0 may have a shape recessed downwards, compared to the side surface of the auxiliary pattern OHP illustrated in FIG. 9B. The recessed insulation part GR0, which is recessed in the opposite direction of a third direction DR3, may be defined on the side surface of the auxiliary pattern OHP exposed by the opening CL-OP. The recessed insulation part GR0 may overlap the opening CL-OP in a plan view. The recessed insulation part GR0 may be formed by being etched together in an etching process of forming the recessed conductive part Sil. This will be described later with reference to FIGS. 12A to 12G.

The auxiliary pattern OHP may include polymer. The auxiliary pattern OHP may include an organic insulation layer. The auxiliary pattern OHP may include thermosetting polymer. The auxiliary pattern OHP may include thermoplastic polymer. However, the material of the auxiliary pattern OHP is not limited thereto, and may be changed.

The second connection pattern CL2 may include a first conductive portion PP1 and a second conductive portion PP2. The first conductive portion PP1 of the second connection pattern CL2 may be disposed on the auxiliary pattern OHP, and cover a portion of the auxiliary pattern OHP. That is, a lower surface of the first conductive portion PP1 of the second connection pattern CL2 may be in contact with an upper surface of the auxiliary pattern OHP. The second conductive portion PP2 of the second connection pattern CL2 may be disposed on the fourth insulation layer INS4.

The opening CL-OP that exposes a portion of the auxiliary pattern OHP may be defined in the second connection pattern CL2. The opening CL-OP may be defined between the first conductive portion PP1 and the second conductive portion PP2. A portion of the second connection pattern CL2 overlapping the auxiliary pattern OHP in a plan view and in contact with a first bump electrode BP1 (see FIG. 10A), to be described later, may be defined as a connection part CTP. The connection part CTP may be disposed adjacent to the opening CL-OP. The connection part CTP may be disposed between the openings CL-OP. The connection part CTP may not overlap the opening CL-OP in a plan view. The second connection pattern CL2 may include a conductive material.

FIG. 9B is a cross-sectional view taken along line B-B′ of FIG. 8 according to an embodiment of the invention. Hereinafter, same components as the components described with reference to FIG. 9A will be denoted as the same reference numerals or symbols, and the descriptions thereof will be omitted or simplified.

Referring to FIG. 9B, on a cross-section taken along line B-B′ of FIG. 8, the width of a first connection pattern CL1 may be larger than the width of an auxiliary pattern OHP. The auxiliary pattern OHP may be disposed on the first connection pattern CL1. Unlike the auxiliary pattern OHP (see FIG. 9A) in FIG. 9A, a recessed insulation part GR0 may not be defined on an side surface of the auxiliary pattern OHP.

A non-connection part NCTP, which is the remaining portion of a second connection pattern CL2 except a connection part CTP, may be defined. The non-connection part NCTP may be a portion of the second connection pattern CL2 not in contact with a first bump electrode BP1 in FIG. 10B. The non-connection part NCTP may be disposed around the connection part CTP. The non-connection part NCTP may be disposed in a position lower than a position of the connection part CTP.

The second connection pattern CL2 may cover the auxiliary pattern OHP on a cross-section taken along line B-B′ of FIG. 8. On the cross-section taken along line B-B′ of FIG. 8, the auxiliary pattern OHP may be covered by the first connection pattern CL1 and the second connection pattern CL2. The second connection pattern CL2 may be disposed on the auxiliary pattern OHP and the first connection pattern CL1. The second connection pattern CL2 may be in contact with the first connection pattern CL1 to be electrically connected to the first connection pattern CL1. The second connection pattern CL2 may be in contact with a pad portion PDP through a contact hole COP. That is, the first connection pattern CL1, the second connection pattern CL2, and the pad portion PDP may be electrically connected to each other.

FIG. 9C is a cross-sectional view taken along line C-C′ of FIG. 8 according to an embodiment of the invention. Hereinafter, same components as the components described with reference to FIGS. 9A and 9B are denoted as the same reference numerals or symbols, and the descriptions thereof will be omitted.

Referring to FIG. 9C, a contact hole COP may be defined in second to fourth insulation layers INS2 to INS4. The contact hole COP may pass through the second to fourth insulation layers INS2 to INS4. A portion of an upper surface of a pad portion PDP may be exposed to the outside by the contact hole COP. A second connection pattern CL2 may extend along inner side surfaces of the second to fourth insulation layers INS2 to INS4 defining the contact hole COP, and extend along the exposed upper surface of the pad portion PDP. The second connection pattern CL2 may be in contact with the exposed upper surface of the pad portion PDP.

FIG. 10A is a cross-sectional view taken along line A-A′ of FIG. 8 after a first pad electrode and a first bump electrode, according to an embodiment of the invention, are bonded to each other. Hereinafter, same components as the components described with reference to FIGS. 9A to 9C are denoted as the same reference numerals or symbols, and the descriptions thereof will be omitted or simplified.

Referring to FIG. 10A, a first conductive portion PP1 of a second connection pattern CL2 may be in contact with a first bump electrode BP1. Accordingly, the first bump electrode BP1 may be electrically connected to the second connection pattern CL2. Since the second connection pattern CL2 is electrically connected to a first connection pattern CL1 and a pad portion PDP, the first bump electrode BP1, the first and second connection patterns CL1 and CL2, and the pad portion PDP may be electrically connected to each other.

When the first bump electrode BP1 and a first adhesive layer CF1 are bonded to a first pad electrode PD1, bonding pressure along a third direction DR3 may be applied. Accordingly, an auxiliary pattern OHP is pressed, so that a tip portion TP′ may more protrude toward an opening CL-OP than the previously-described tip portion TP (see FIG. 9A). The tip portion TP′ may more protrude toward the opening CL-OP than a recessed conductive part Sil by a first protruding length TDP1′ in a plan view. The first protruding length TDP1′ may be about 0.7 μm or more.

The first adhesive layer CF1 may bond the first pad electrode PD1 and the first bump electrode BP1 to each other. The first adhesive layer CF1 may be in contact with the first pad electrode PD1 and the first bump electrode BP1. The first adhesive layer CF1 may fill the opening CL-OP. The first adhesive layer CF1 may fill a space between the driving part DC (see FIG. 7) and the display panel DP (see FIG. 7). Herein, the first adhesive layer CF1 may not include a conductive material such as nano-conductive particles.

The first adhesive layer CF1 may bond the first pad electrode PD1 and the first bump electrode BP1 to each other while surrounding the tip portion TP′. The first adhesive layer CF1 may include a first adhesive portion ANC1 and a second adhesive portion ANC2. The first adhesive portion ANC1 may be a portion of the first adhesive layer CF1 positioned under the tip portion TP′. The second adhesive portion ANC2 may be a portion of the first adhesive layer CF1 positioned above the tip portion TP′.

The first adhesive portion ANC1 and the second adhesive portion ANC2 may fix the auxiliary pattern OHP not to be displaced even if stress is applied to the auxiliary pattern OHP. The tip portion TP′, positioned between the first adhesive portion ANC1 and the second adhesive portion ANC2, may serve as a stopper that stops the auxiliary pattern OHP from moving. When the stress is applied to the auxiliary pattern OHP in a third direction DR3 that is an upward direction, the second adhesive portion ANC2, disposed above the tip portion TP′, may stop the tip portion TP′ from moving in the stress direction. When the stress is applied to the auxiliary pattern OHP in the opposite direction of the third direction DR3 that is a downward direction, the first adhesive portion ANC1, disposed under the tip portion TP′, may stop the tip portion TP′ from moving in the stress direction. Accordingly, even though the stress is applied to the auxiliary pattern OHP, the position of the auxiliary pattern OHP is not changed, and the first pad electrode PD1 and the first bump electrode BP1 may remain in contact with each other. Accordingly, the electrical connection characteristics between the first pad electrode PD1 and the first bump electrode BP1 may be improved.

FIG. 10B is a cross-sectional view taken along line B-B′ of FIG. 8 after a first pad electrode and a first bump electrode, according to an embodiment of the invention, are bonded to each other.

Referring to FIG. 10B, an auxiliary pattern OHP may be surrounded by a first connection pattern CL1 and a second connection pattern CL2. A protruding portion, such as the tip portion TP′ (see FIG. 10A) in FIG. 10A, does not exist on a portion of the auxiliary pattern OHP not corresponding to the opening CL-OP (see FIG. 10A), so that there may be no component to fix the position of the auxiliary pattern OHP. However, since the second connection pattern CL2 may be disconnected in case of forming the opening CL-OP (see FIG. 10A) as illustrated in FIG. 10A, it may be difficult for the second connection pattern CL2 to be electrically connected to a pad portion PDP.

Therefore, the tip portion TP′ (see FIG. 10A) may be disposed on one portion of a first pad electrode PD1, as illustrated in FIG. 10A, to fix the position of the auxiliary pattern OHP, and on the remaining portion of the first pad electrode PD1, the second connection pattern CL2 may extend along a contact hole COP to be electrically connected to the pad portion PDP as illustrated in FIG. 10B.

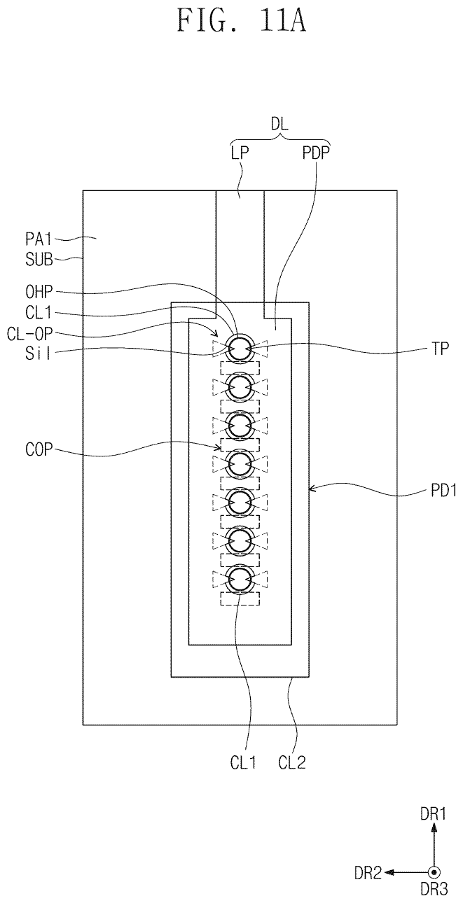

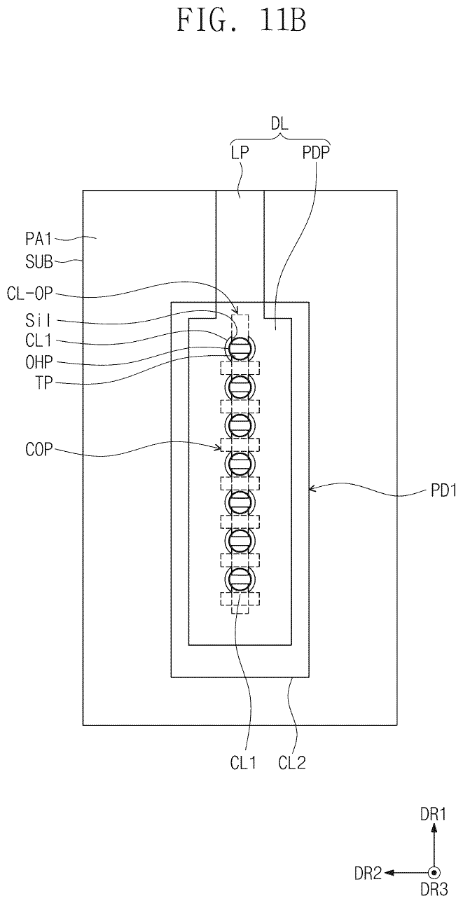

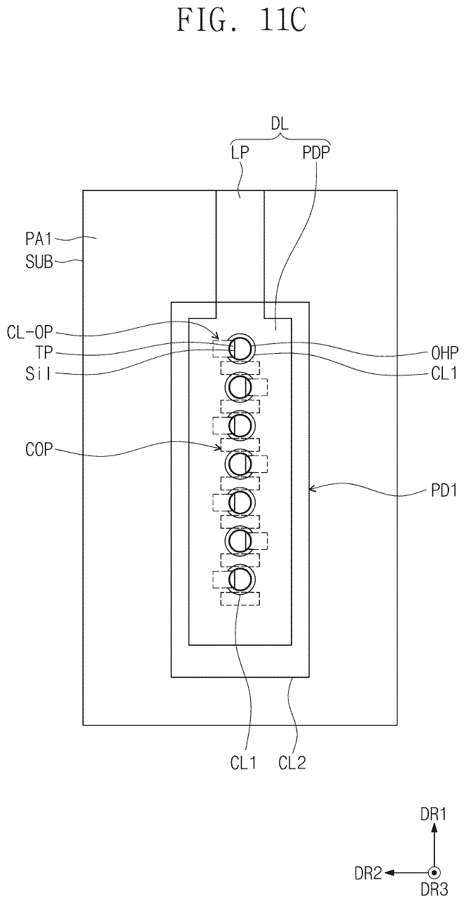

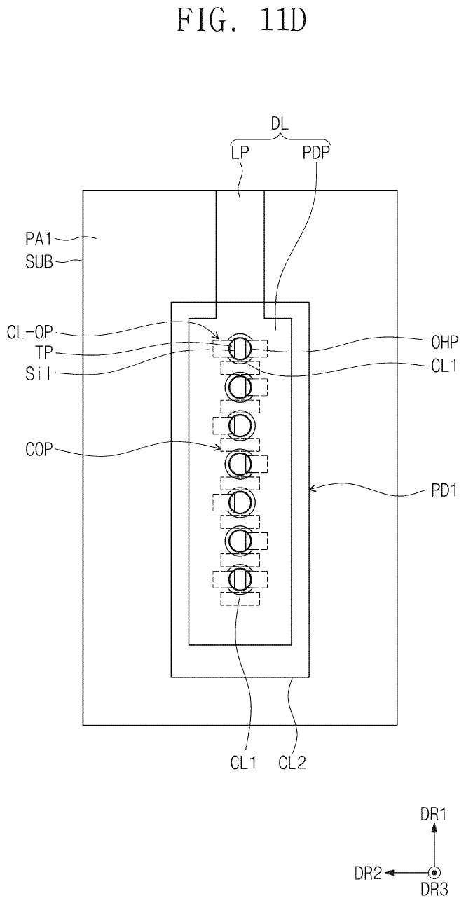

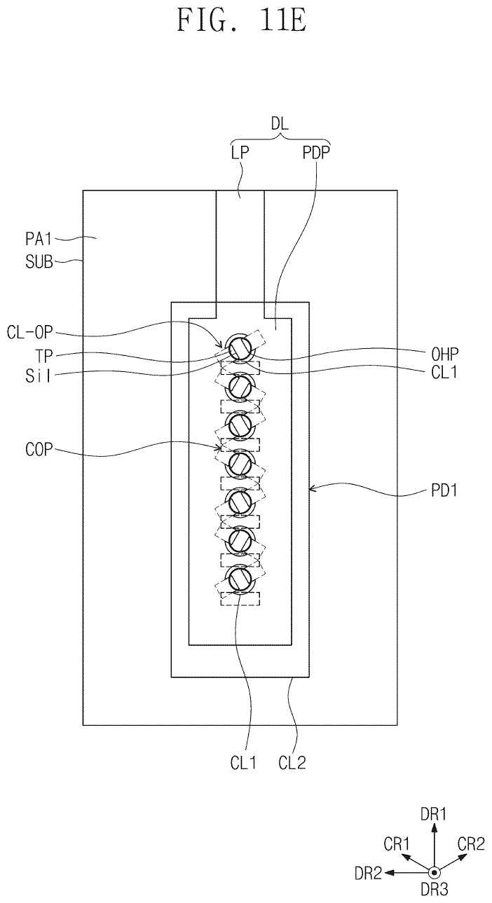

FIGS. 11A to 11F are plan views illustrating arrangements of an opening and an auxiliary pattern according to an embodiment of the invention.

Referring to FIGS. 11A to 11F, shapes and arrangements of the auxiliary pattern OHP and the opening CL-OP may be changed.

Referring to FIG. 11A, a plurality of auxiliary patterns OHP may be disposed along a first direction DR1. A plurality of openings CL-OP may be disposed apart from each other in a second direction DR2 with the auxiliary patterns OHP therebetween. That is, one column of openings CL-OP may be disposed on the left side of the auxiliary patterns OHP, and one column of openings CL-OP may be disposed on the right side of the auxiliary patterns OHP. The openings CL-OP may each have a triangular shape in a plan view. Only portions of the openings CL-OP may overlap the auxiliary patterns OHP in a plan view, respectively. A planar shape of a recessed conductive part Sil may correspond to a planar shape of the opening CL-OP.

Referring to FIG. 11B, a plurality of openings CL-OP may be disposed apart from each other in a first direction DR1 with auxiliary patterns OHP therebetween. At this time, the openings CL-OP and the auxiliary patterns OHP may be alternately disposed along the first direction DR1. A planar shape of each of the openings CL-OP may be a quadrilateral shape. A portion of an upper side of the opening CL-OP disposed between the auxiliary patterns OHP may overlap the auxiliary pattern OHP, and a portion of a lower side may overlap the auxiliary pattern OHP in a plan view.

Referring to FIG. 11C, a plurality of openings CL-OP may one-to-one correspond to a plurality of auxiliary patterns OHP. The openings CL-OP may be disposed on the left side of the auxiliary patterns OHP which correspond to odd rows among the auxiliary patterns OHP. The openings CL-OP may be disposed on the right side of the auxiliary patterns OHP which correspond to even rows among the auxiliary patterns OHP. One portion of each of the openings CL-OP adjacent to the auxiliary pattern OHP may overlap the auxiliary pattern OHP in a plan view.

Referring to FIG. 11D, openings CL-OP may be disposed on opposite sides of some auxiliary patterns among auxiliary patterns OHP. The openings CL-OP may be disposed on the left or right sides of the rest of the auxiliary patterns OHP among the auxiliary patterns OHP.

Referring to FIG. 11E, openings CL-OP may be disposed apart from each other with an auxiliary pattern OHP therebetween. At this time, two openings CL-OP, spaced apart from each other with the auxiliary pattern OHP therebetween, may be disposed along a first diagonal direction CR1 or a second diagonal direction CR2.

Referring to FIG. 11F, openings CL-OP may be disposed on the left or right sides of auxiliary patterns OHP. The opening CL-OP and the auxiliary pattern OHP corresponding to an odd row may be disposed such that the auxiliary pattern OHP is positioned on the left side, and the opening CL-OP is positioned on the right side. The opening CL-OP and the auxiliary pattern OHP corresponding to an even row may be disposed such that the opening CL-OP is positioned on the left side, and the auxiliary pattern OHP is positioned on the right side. The auxiliary patterns OHP and the openings CL-OP may be alternately disposed along a first direction DR1.

FIGS. 12A to 12G are cross-sectional views illustrating some operations of a manufacturing method of a display device according to an embodiment of the invention. Hereinafter, same components as the components previously described are denoted as the same reference numerals or symbols, and the descriptions thereof will be omitted.

Referring to FIGS. 12A and 12B, a pad portion PDP is formed on a first insulation layer INS1, and on the pad portion PDP, a second insulation layer INS2, a third insulation layer INS3, and a fourth insulation layer INS4 may be sequentially formed.

Referring to FIG. 12C, a preliminary first connection pattern CL1-P may be formed on the fourth insulation layer INS4. An auxiliary pattern OHP, protruding toward a third direction DR3 that is an upward direction, may be formed on the preliminary first connection pattern CL1-P. The preliminary first connection pattern CL1-P may include the same material as a material of the first connection electrode CNE1 in FIG. 5, and may be formed through the same process as the process through which the first connection electrode CNE1 is formed.

Referring to FIG. 12D, a preliminary second connection pattern layer CL2-P that covers the preliminary first connection pattern CL1-P and the auxiliary pattern OHP may be formed. The preliminary second connection pattern layer CL2-P may include the same material as a material of the second connection electrode CNE2 in FIG. 5, and may be formed through the same process as the process through which the second connection electrode CNE2 is formed.

In addition, a photoresist pattern PR in which a photo opening PR-OP is defined may be formed on the preliminary second connection pattern layer CL2-P. After a photoresist layer containing a photosensitive material is formed, light is emitted to a portion of the photoresist layer corresponding to the photo opening PR-OP, or emitted to a portion except the photo opening PR-OP, to thereby form the photoresist pattern PR. The photo opening PR-OP may correspond to an opening CL-OP (see FIG. 12E).

Referring to FIG. 12E, the preliminary second connection pattern layer CL2-P (see FIG. 12D) may be etched to form the opening CL-OP that exposes a portion of the auxiliary pattern OHP, thereby forming a second connection pattern CL2. That is, the preliminary second connection pattern layer CL2-P not overlapping the photoresist pattern PR in a plan view may be etched. The preliminary second connection pattern layer CL2-P (see FIG. 12D) corresponding to the photo opening PR-OP may be etched. At this time, the preliminary second connection pattern layer CL2-P may be wet etched or dry etched.

Referring to FIGS. 12E and 12F, in a state where the photoresist pattern PR remains, the preliminary first connection pattern CL1-P is etched to form a first connection pattern CL1. That is, in the etching of FIG. 12E, an over-etching, which is to etch more than the depth to be etched for forming the second connection pattern CL2, is performed. The formed first connection pattern CL1 may include a recessed conductive part Sil that is more recessed toward the center of the auxiliary pattern OHP than the auxiliary pattern OHP in a plan view. Not only a portion of the preliminary first connection pattern CL1-P not overlapping the auxiliary pattern OHP in a plan view, but also a portion of the preliminary first connection pattern CL1-P disposed under the auxiliary pattern OHP may be etched together to form the recessed conductive part Sil. Accordingly, a tip portion TP, which is a portion of the auxiliary pattern OHP relatively more protruding toward the opening CL-OP than the first connection pattern CL1, may be formed. The first connection pattern CL1 and the auxiliary pattern OHP may form an undercut shape on a cross-section together.

At this time, a side surface of the auxiliary pattern OHP, exposed by the photo opening PR-OP and the opening CL-OP, may also be etched together to thereby form a recessed insulation part GR0 which is recessed downwards in the opposite direction of a third direction DR3.

Referring to FIG. 12G, the photoresist pattern PR (see FIG. 12F) may be removed.

According to an embodiment of the invention, since an auxiliary pattern includes a tip portion more protruding than a first connection pattern, and an adhesive layer is bonded while surrounding the tip portion, the auxiliary pattern may not be displaced even if external stress is applied to the auxiliary pattern.

Accordingly, even after being bonded, a pad electrode and a bump electrode may have improved electrical connection characteristics therebetween.

Although the embodiments of the invention have been described, it is understood that the invention should not be limited to these embodiments but various changes and modifications can be made by one ordinary skilled in the art within the spirit and scope of the invention as hereinafter claimed. Therefore, the technical scope of the invention should not be limited to the contents described in the detailed description of the specification, but should be defined by the claims.

What is claimed is:

1. A display device comprising:
a display panel including a display region in which a pixel is disposed, and a non-display region in which a pad electrode is disposed;
a driving part disposed on the display panel, and including a bump electrode disposed to correspond to the pad electrode; and
an adhesive layer in contact with the pad electrode and the bump electrode,
wherein the pad electrode includes
a first connection pattern containing a conductive material,
an auxiliary pattern disposed on the first connection pattern, protruding toward the bump electrode, and containing an insulating material, and
a second connection pattern, which contains a conductive material, of which a portion is disposed on the auxiliary pattern, and in which an opening that exposes a portion of the auxiliary pattern is defined,
wherein the auxiliary pattern includes a tip portion more protruding toward the opening than the first connection pattern.

2. The display device of claim 1, wherein the auxiliary pattern and the first connection pattern form an undercut shape in a cross-sectional view.

3. The display device of claim 1, wherein the second connection pattern comprises a connection part which is in contact with the bump electrode, and
the opening does not overlap the connection part in a plan view.

4. The display device of claim 3, wherein the opening is provided in plurality, and
the plurality of openings are disposed apart from each other with the auxiliary pattern therebetween in the plan view.

5. The display device of claim 3, wherein the auxiliary pattern is provided in plurality,
the opening is provided in plurality, and
the plurality of openings one-to-one correspond to the plurality of auxiliary patterns.

6. The display device of claim 3, wherein the opening is provided in plurality,
the auxiliary pattern is provided in plurality, and
the plurality of openings and the plurality of auxiliary patterns are alternately disposed along a first direction.

7. The display device of claim 1, wherein a side surface of the auxiliary pattern exposed by the opening comprises a recessed insulation part which is recessed downwards.

8. The display device of claim 1, wherein the adhesive layer surrounds the tip portion and bonds the pad electrode and the bump electrode to each other.

9. The display device of claim 1, wherein the first connection pattern comprises a recessed conductive part which is more recessed toward a center of the auxiliary pattern than the auxiliary pattern in a plan view.

10. The display device of claim 9, wherein the tip portion more protrudes toward the opening than the recessed conductive part by a first protruding length, and the first protruding length is about 0.4 micrometers (μm) or more.

11. The display device of claim 9, wherein the recessed conductive part more protrudes toward the opening than a side surface of the portion of the second connection pattern disposed on the auxiliary pattern among side surfaces of the second connection pattern, which define the opening in a cross-sectional view.

12. The display device of claim 1, wherein the second connection pattern is in contact with the bump electrode.

13. The display device of claim 1, further comprising:
a signal line including a wire portion connected to the pixel and a pad portion extending from an end of the wire portion and having a larger width than a width of the wire portion; and
an insulation layer disposed on the pad portion and covering the pad portion,
wherein the second connection pattern is electrically connected to the pad portion by a contact hole passing through the insulation layer.

14. The display device of claim 13, wherein the contact hole does not overlap the auxiliary pattern in a plan view.

15. The display device of claim 1, wherein the adhesive layer does not comprise a conductive material.

16. A display device comprising:
a display panel including a pad electrode;
a driving part disposed on the display panel, and including a bump electrode disposed to correspond to the pad electrode; and
an adhesive layer in contact with the pad electrode and the bump electrode,
wherein the pad electrode includes
a first connection pattern containing a conductive material,
an auxiliary pattern disposed on the first connection pattern, protruding toward the bump electrode, and containing an insulating material, and
a second connection pattern, which contains a conductive material, of which a portion is disposed on the auxiliary pattern, and in which an opening that exposes a portion of the auxiliary pattern is defined,
wherein the first connection pattern includes a recessed conductive part which is more recessed toward a center of the auxiliary pattern than the auxiliary pattern in a plan view.

17. A manufacturing method of a display device comprising:
forming an auxiliary pattern, which protrudes upwards and contains an insulating material, on a preliminary first connection pattern containing a conductive material;
forming a preliminary second connection pattern layer which covers the preliminary first connection pattern and the auxiliary pattern and contains a conductive material;
performing first etching of the preliminary second connection pattern layer such that a second connection pattern is formed by forming an opening that exposes a portion of the auxiliary pattern in the preliminary second connection pattern layer; and
performing second etching of the preliminary first connection pattern such that a first connection pattern including a recessed conductive part more recessed toward a center of the auxiliary pattern than the auxiliary pattern in a plan view is formed.

18. The manufacturing method of claim 17, wherein the performing of the first etching comprises:
forming a photoresist pattern on the preliminary second connection pattern layer; and
forming the second connection pattern by etching a portion of the preliminary second connection pattern layer not overlapping the photoresist pattern in the plan view,
wherein, in the performing of the second etching, the preliminary first connection pattern is etched to form the first connection pattern in a state where the photoresist pattern remains.

19. The manufacturing method of claim 17, wherein in the performing of the second etching, a recessed insulation part, which is recessed downwards, is formed in a side surface of the auxiliary pattern exposed by the opening.

20. The manufacturing method of claim 17, wherein the first connection pattern and the auxiliary pattern form an undercut shape in a cross-sectional view.
